(19) United States
(12) Patent Application Publication
(10) Pub. No.: US 2010/0317196 A1
(43) Pub. Date: Dec. 16, 2010

(54) METHOD FOR MANUFACTURING SEMICONDUCTOR DEVICE

(76) Inventor: Hiroko NAKAMURA, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/712,910

(22) Filed: Feb. 25, 2010

(30) Foreign Application Priority Data
Jun. 15, 2009 (JP) 2009-142609

(51) Int. Cl. H01L 21/308

(52) U.S. Cl. 438/736; 257/E21.235

(57) ABSTRACT

A method for manufacturing a semiconductor device, includes: forming a first resist on a workpiece; patterning the first resist by performing selective exposure, baking, and development on the first resist; forming a second resist on the workpiece after the patterning the first resist; patterning the second resist by performing selective exposure, baking, and development on the second resist to selectively remove a part of the second resist and remove the first resist left on the workpiece; and processing the workpiece by using the patterned second resist as a mask.

### CROSS-REFERENCE TO RELATED APPLICATIONS

This application is based upon and claims the benefit of priority from the prior Japanese Patent Application No. 2009-142609, filed on Jun. 15, 2009; the entire contents of which are incorporated herein by reference.

### BACKGROUND OF THE INVENTION

1. Field of the Invention

This invention relates to a method for manufacturing a semiconductor device.

2. Background Art

The progress of device miniaturization is more rapid than wavelength reduction and NA increase in exposure apparatuses. Hence, it is difficult to form a fine pattern by single exposure in view of resolution performance.

In a method known as double patterning or multiple patterning, the desired pattern is divided into a plurality of patterns, each of which is subjected to resist patterning followed by transfer of the resist pattern to a hard mask. The hard mask pattern thus obtained is used as a mask to perform etching, thereby obtaining the desired workpiece pattern. However, use of a hard mask increases the number of processes such as forming a hard mask film, etching, and stripping the hard mask in addition to the resist patterning process. This causes the problem of cost increase.

In this context, a spacer process is proposed for formation of a half-pitch pattern. In this method, a sacrificial pattern (spacer) is first formed, a sidewall material is then formed on its sidewall, and the sacrificial pattern is removed. Thus, unfortunately, there are restrictions on the patterns which can be formed by this method.

On the other hand, there are some methods proposed for double patterning of remaining patterns (line patterns, island patterns and dot patterns), such as a method for using a bottom anti-reflection coating (BARC) as a hard mask, and a method for using stacked resist patterns as an etching mask (including UV curing, ion implantation, baking for insolubilization, freezing material, stacked process of negative-type resist and positive-type resist, and stacked process of positive-type resist and positive-type resist based on the difference in PEB (post-exposure bake) temperature). However, use of a BARC as a hard mask involves resist patterning on the processed BARC, which interferes with the anti-reflection performance. Stacked resist films cannot be used for double patterning of opening (extraction) patterns such as space patterns and hole patterns, because patterns are stacked in sequence.

In order to form copper or other metal interconnection by plating, it is necessary to form opening lines (space). Furthermore, even in the same design rule, contact hole patterns have a smaller margin than line patterns and have a need for the double patterning than the line patterns. However, despite these needs, double patterning has the problem of lacking useful methods for forming an opening pattern except the high-cost process using a hard mask.

JP-A 3-136233 (1991) (Kokai) discloses a patterning method in which a positive-type resist pattern is first formed, a negative-type resist thinner than the positive-type resist is then formed and entirely irradiated with ultraviolet radiation, and then the positive-type resist is removed to obtain a pattern based on the remaining negative-type resist. However, this method only forms an inverted pattern of the initial positive-type resist pattern, and the pattern thus formed does not have a finer pitch than that positive-type resist pattern.

### SUMMARY OF THE INVENTION

According to an aspect of the invention, there is provided a method for manufacturing a semiconductor device, including: forming a first resist on a workpiece; patterning the first resist by performing selective exposure, baking, and development on the first resist; forming a second resist on the workpiece after the patterning the first resist; patterning the second resist by performing selective exposure, baking, and development on the second resist to selectively remove a part of the second resist and remove the first resist left on the workpiece; and processing the workpiece by using the patterned second resist as a mask.

### BRIEF DESCRIPTION OF THE DRAWINGS

FIGS. 1A to 1E are schematic cross-sectional views showing a process for manufacturing a semiconductor device according to a first embodiment of the invention;

FIGS. 2A to 2C are plan views showing particular processes in FIGS. 1A to 1E;

FIG. 3A is a schematic plan view of a reticle used for exposure when patterning a first resist shown in FIGS. 1A to 1E, and FIG. 3B is a schematic plan view of a reticle used for exposure when patterning a second resist shown in FIGS. 1A to 1E;

FIGS. 4A to 4C are schematic views corresponding to FIGS. 2A to 2C in the case where the pattern to be formed is a line-shaped space pattern (opening pattern);

FIG. 5A is a schematic plan view of a reticle used for a pattern formation in FIG. 4A, and FIG. 5B is a schematic plan view of a reticle used for a pattern formation in FIG. 4B;

FIGS. 6A to 6C are schematic views corresponding to FIGS. 2A to 2C in the case where the pattern to be formed is a line-shaped space pattern (opening pattern);

FIG. 7A is a schematic plan view of a reticle used for a pattern formation in FIG. 6A, and FIG. 7B is a schematic plan view of a reticle used for a pattern formation in FIG. 6B;

FIGS. 8A to 8G are schematic cross-sectional views showing a process for manufacturing a semiconductor device according to a second embodiment of the invention;

FIGS. 9A to 9C are plan views showing particular processes in FIGS. 8A to 8G;

FIGS. 10A to 10C are plan views showing particular processes in FIGS. 11A to 11G;

FIGS. 11A to 11G are schematic cross-sectional views showing a process for manufacturing a semiconductor device according to a third embodiment of the invention;

FIGS. 12A to 12D are plan views showing particular processes in FIGS. 13A to 14G;

FIGS. 13A to 13G are schematic cross-sectional views showing a process for manufacturing a semiconductor device according to a fourth embodiment of the invention and correspond to the A-A cross section in FIGS. 12A to 12D;

FIGS. 14A to 14G are schematic cross-sectional views showing the process for manufacturing a semiconductor device according to the fourth embodiment of the invention and correspond to the B-B cross section in FIGS. 12A to 12D;

FIGS. 15A and 15B are schematic cross-sectional views showing a process for manufacturing a semiconductor device according to a variation of the invention;

FIGS. 16A to 16I are schematic cross-sectional views showing a process for manufacturing a semiconductor device of a first comparative example;

FIGS. 17A to 17C are plan views showing particular processes in FIGS. 16A to 16I; and

FIGS. 18A to 20I are schematic cross-sectional views showing a process for manufacturing a semiconductor device of a second comparative example.

### DETAILED DESCRIPTION

Embodiments of the invention will now be described with reference to the drawings.

### First Embodiment

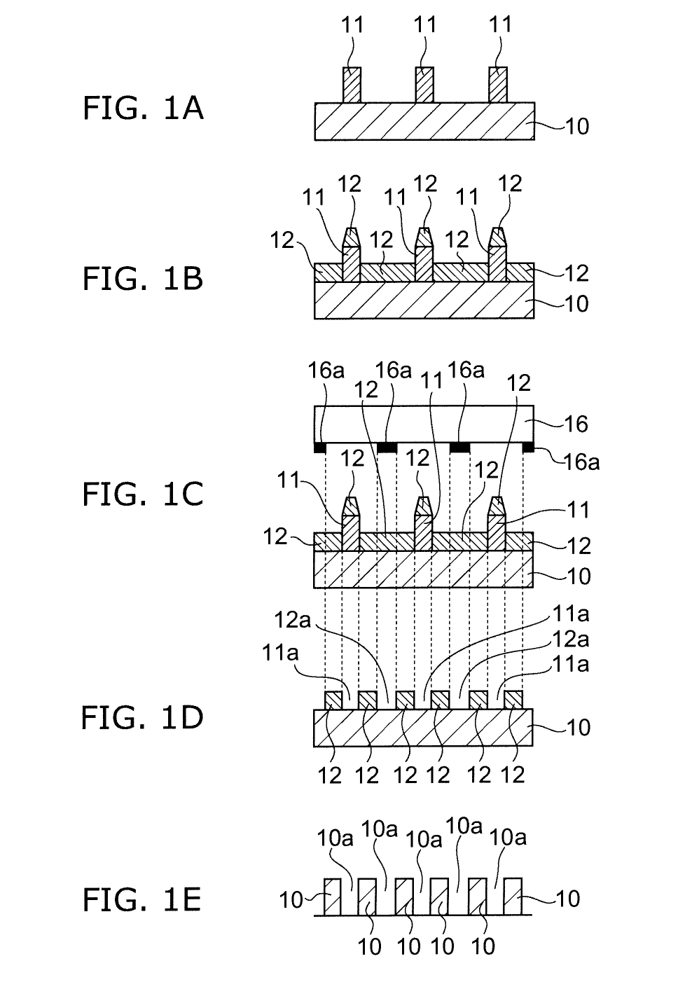

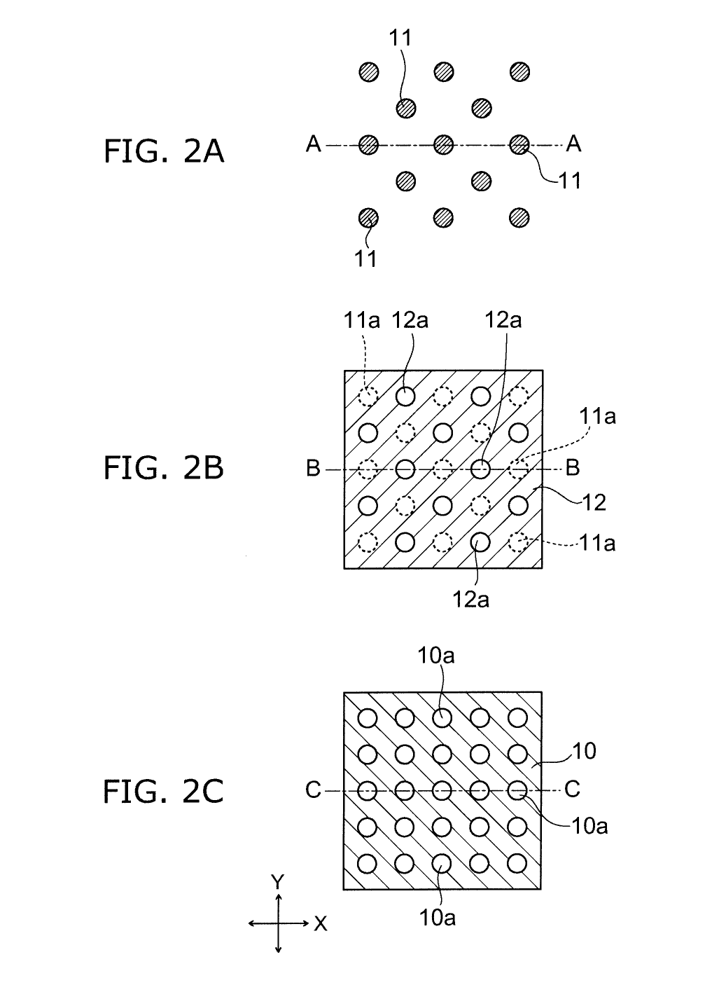

FIGS. 1A to 1E are schematic cross-sectional views showing a process for manufacturing a semiconductor device according to a first embodiment of the invention. FIGS. 2A to 2C show plan views of particular processes in FIGS. 1A to 1E. The A-A cross section in FIG. 2A corresponds to FIG. 1A, the B-B cross section in FIG. 2B corresponds to FIG. 1D, and the C-C cross section in FIG. 2C corresponds to FIG. 1E.

FIGS. 1A to 2C show the process for selectively forming openings in a workpiece 10. The workpiece 10 is illustratively an insulating film, conductive film, or semiconductor film formed on a semiconductor wafer. Alternatively, the workpiece 10 may be a semiconductor wafer itself.

In this embodiment, as shown in FIG. 2C, a plurality of holes 10a having a circular planar shape with an equal diameter, for instance, are formed in the workpiece 10. These holes 10a correspond to contact holes for connecting between upper and lower layers in a semiconductor device.

Two orthogonal directions X and Y are introduced in FIG. 2C. The holes 10a are equally spaced in each of the X and Y directions. For instance, the spacing between the holes 10a in the X direction is nearly equal to the diameter of the hole 10a, and the spacing between the holes 10a in the Y direction is also nearly equal to the diameter of the hole 10a. In recent years, the diameter and arrangement pitch of contact holes have been increasingly downscaled, and a pattern corresponding to such a densely arranged contact hole pattern has become difficult to form in a resist by single exposure in view of resolution performance.

Against this background, in this embodiment, the contact hole pattern to be formed in the workpiece 10 is divided into two patterns (first and second patterns) having a lower arrangement density in terms of pattern data processing. And two reticles respectively corresponding to the two patterns (first and second patterns) are used to transfer the two patterns to a resist. Here, in FIG. 2B, the pattern of holes 11a shown by dashed lines corresponds to the first pattern, and the pattern of holes 12a shown by solid lines corresponds to the second pattern.

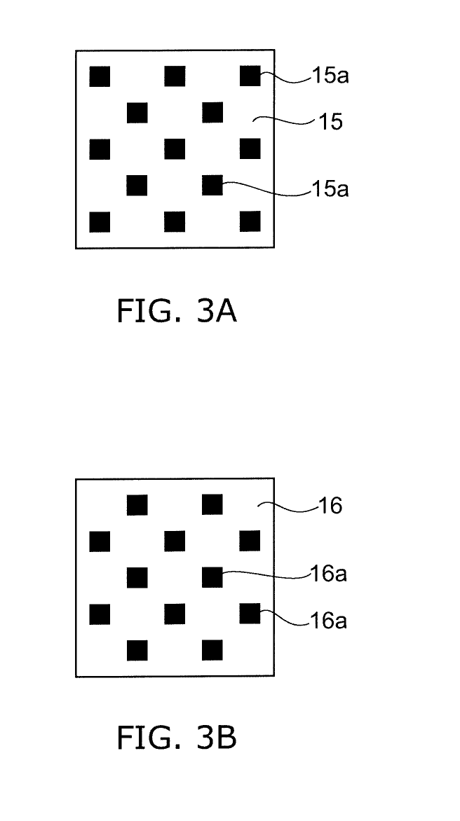

First, as shown in FIGS. 1A and 2A, a pattern of a first resist 11 is formed on the workpiece 10. Specifically, the first resist 11, which is a positive-type resist, is formed entirely on the workpiece 10, and then a reticle (or photomask) 15 shown in FIG. 3A is used to perform selective exposure. The reticle 15 has a structure in which an opaque film or half-tone film 15a is selectively formed on a substrate transparent to exposure light. The pattern of this opaque film or half-tone film 15a corresponds to the pattern of holes 11a (first pattern) shown by dashed lines in FIG. 2B.

The aforementioned exposure is followed by baking and development. Because the first resist 11 is a positive-type resist film, the unexposed portion is left on the workpiece 10 as shown in FIGS. 1A and 2A. The first resist 11 is left on the workpiece 10 in a pillar configuration, which corresponds to an inverted pattern of the holes 11a (opening pattern) shown in FIG. 2B.

Next, as shown in FIG. 1B, a second resist 12, which is a negative-type resist, is formed on the workpiece 10. Here, the thickness of the second resist 12 is adjusted so that the side surface of the pillar-shaped first resist 11 is not entirely covered with the second resist 12. For instance, as an example of such adjustment, the contact angle of the second resist 12 with respect to the first resist 11 is increased so that the second resist 12 formed in the space portion of the first resist 11 is not connected to the second resist 12 formed on the upper surface of the first resist 11. Furthermore, in view of the area of the space portion of the first resist 11, it is also necessary to adjust the thickness of the second resist 12 so that the second resist 12 can cover the space portion. Moreover, in forming the second resist 12, for instance, a solution of the material for the second resist 12 dissolved in an organic solvent is applied onto the workpiece 10 and then dried. Here, the combination of materials needs to be determined so that the first resist 11 is not dissolved when the second resist 12 is applied.

That is, the second resist 12 covers the surface of the workpiece 10 in the portion where the first resist 11 does not exist (the space portion of the first resist 11), and is also left on the upper surface of the pillar-shaped first resist 11. The thickness of the second resist 12 is smaller than the thickness (or height) of the first resist 11, and part of the side surface on the upper end side of the first resist 11 is not covered with the second resist 12.

Next, as shown in FIG. 1C, a reticle (or photomask) 16 is used to perform selective exposure on the second resist 12. As shown in FIG. 3B, the reticle 16 has a structure in which an opaque film or half-tone film 16a is selectively formed on a substrate transparent to exposure light. The pattern of this opaque film or half-tone film 16a corresponds to the pattern of holes 12a (second pattern) shown by solid lines in FIG. 2B. The pattern image transferred to the second resist 12 by this exposure corresponds to the pattern of holes 12a (opening pattern) shown in FIG. 2B. Here, the first resist 11 is also exposed to light. Although the second resist 12 exists on the upper surface of the first resist 11, the second resist 12 scarcely absorbs light, and hence the first resist 11 is also irradiated with exposure light.

This exposure is followed by a baking (post-exposure bake, PEB) process, and further followed by development. The exposed portion of the second resist 12, which is a negative-type resist, undergoes crosslinking and becomes insoluble in the developer. On the other hand, the exposed portion of the first resist 11 (all the pillar-shaped portions left on the workpiece 10), which is a positive-type resist, becomes soluble in the developer because the protecting group having a dissolution inhibiting effect coupled to the polymer is disengaged. Then, because a portion of the side surface of the first resist 11 is not covered with the second resist 12, the first resist 11 is dissolved in the developer from this portion and removed from the upper surface of the workpiece 10.

The state after development is shown in FIGS. 1D and 2B. By this development, a combined pattern of the holes 11a (first pattern) and the holes 12a (second pattern) is formed in the second resist 12. The holes 12a are formed by the process in which the unexposed portion of the second resist 12 is dissolved and removed by the developer, and the holes 11a are formed by the process in which the pillar-shaped first resist 11 is dissolved and removed by the same developer. The pattern of the holes 11a and 12a is a combined pattern of the aforementioned first and second patterns and is formed at a pitch, which is finer than the pattern pitch of the first pattern and the pattern pitch of the second pattern.

Then, the second resist 12 with these holes 11a and 12a formed therein is used as a mask to selectively etch the underlying workpiece 10. Thus, as shown in FIGS. 1E and 2C, the desired pattern of holes 10a is formed in the workpiece 10.

In contrast to the conventional double patterning method using a hard mask, this embodiment only needs processes on resists (first resist 11 and second resist 12) and does not need such processes as forming, etching, and stripping a hard mask. This enables reduction in the number of processes, and it allows cost reduction.

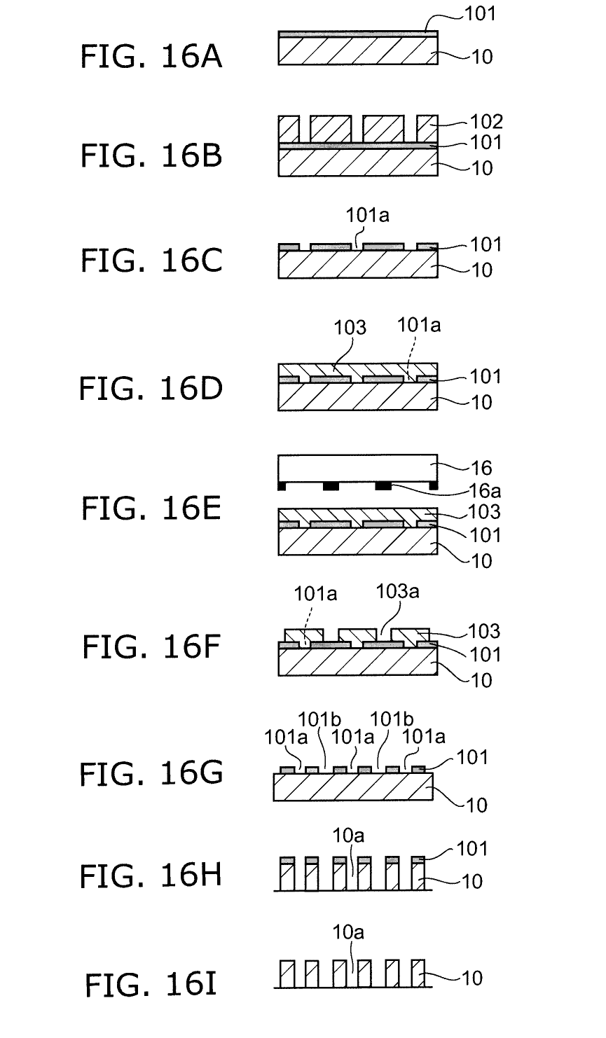

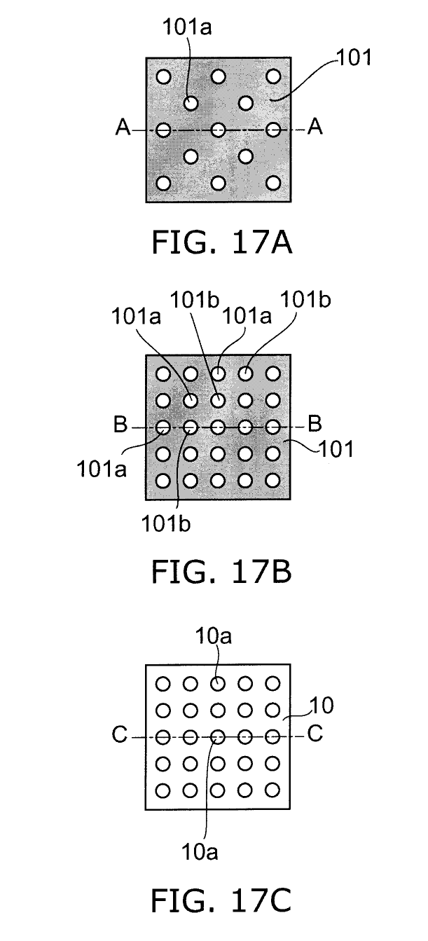

FIGS. 16A to 16I are schematic cross-sectional views showing a process for manufacturing a semiconductor device of a first comparative example for comparison with the embodiment of the invention. FIGS. 17A to 17C show plan views of particular processes in FIGS. 16A to 16I. The A-A cross section in FIG. 17A corresponds to FIG. 16C, the B-B cross section in FIG. 16B corresponds to FIG. 16G, and the C-C cross section in FIG. 17C corresponds to FIG. 16I.

First, as shown in FIG. 16A, a hard mask 101 is formed on the workpiece 10. Next, as shown in FIG. 16B, a first resist 102 is formed on the hard mask 101 and then patterned. This first resist 102 is used as a mask to perform etching. Thus, as shown in FIGS. 16C and 17A, holes 101a are selectively formed in the hard mask 101.

Next, as shown in FIG. 16D, a second resist 103 is formed on the workpiece 10 so as to cover the hard mask 101. Subsequently, as shown in FIG. 16E, a reticle 16 is used to perform selective exposure. The reticle 16 has a structure in which an opaque film (or half-tone film) 16a is selectively formed on a substrate transparent to exposure light.

The aforementioned exposure is followed by baking and development. Because the second resist 103 is a negative-type resist, the unexposed portion is removed, and holes 103a are formed as shown in FIG. 16F. The second resist 103 with these holes 103a formed therein is used as a mask to perform etching. Thus, as shown in FIGS. 16G and 17B, holes 101b are formed in the hard mask 101.

The hard mask 101 with the holes 101a and the holes 101b formed therein is used as a mask to etch the workpiece 10. Thus, as shown in FIG. 16H, holes 10a are formed in the workpiece 10. Then, the hard mask 101 left on the surface of the workpiece 10 is removed. Thus, as shown in FIGS. 16I and 17C, the workpiece 10 with the holes 10a formed therein is obtained.

In contrast, in this embodiment, the first resist 11 is first formed on the workpiece 10 as a remaining pattern (island pattern, dot pattern), which is an inverted pattern of the first pattern to serve as a final opening pattern. Subsequently, the first resist 11 is removed to form the opening pattern. That is, in this embodiment, a fine opening pattern, which is difficult to form by single exposure, can be formed at low cost without using a hard mask. Furthermore, there is no need of the process for insolubilizing the first resist 11. Moreover, the first resist 11 can be removed when the second resist 12 is developed because the first resist 11 is dissolved in the same developer. Thus, a low-cost process with a smaller number of processes can be realized.

In the foregoing, a method for forming a pattern of holes periodically arranged at an equal pitch is described. However, this method is also applicable to forming a pattern of holes non-periodically arranged at random pitches. More specifically, first, in terms of pattern data processing, the pattern to be finally formed is divided into a first pattern and a second pattern having a lower density. Then, as in the foregoing, it is possible to form a pattern made of a first resist corresponding to an inverted pattern of the first pattern (opening pattern), and a pattern made of a second resist corresponding to the second pattern. Furthermore, the size of holes is not limited to a single size, but this method can form a pattern including elliptical holes having different aspect ratios.

In order to form copper interconnection by plating, there is a case to form a line-shaped opening (trench pattern) in a workpiece. This embodiment also enables double patterning of a fine-pitch trench pattern, which is difficult to form by single exposure.

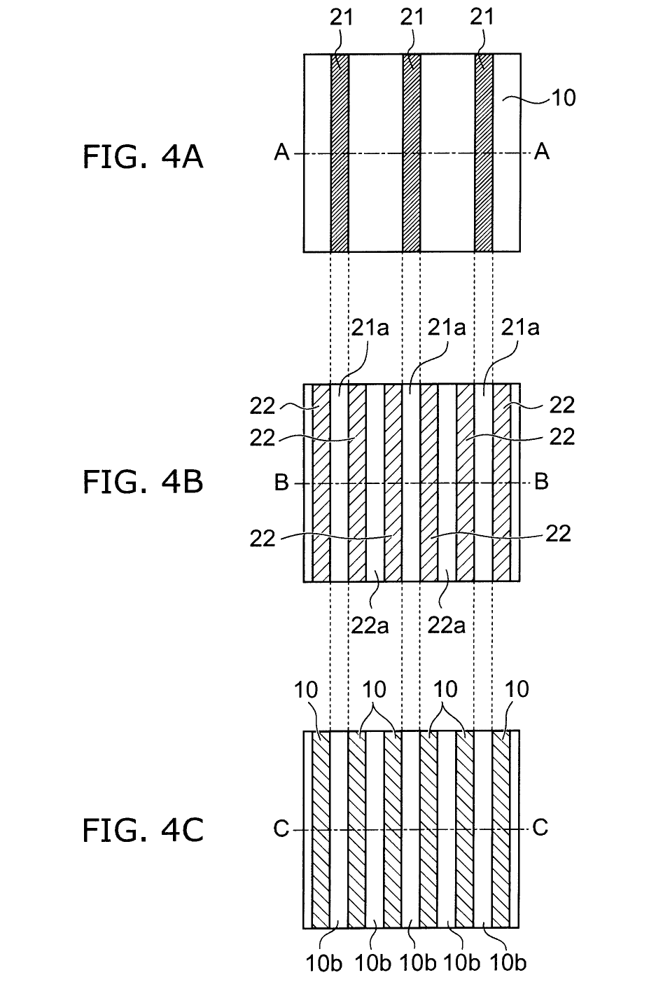

The process cross-sectional view for the trench pattern is similar to FIG. 1. For the trench pattern, FIG. 4A shows a plan view corresponding to FIG. 1A, FIG. 4B shows a plan view corresponding to FIG. 1D, and FIG. 4C shows a plan view corresponding to FIG. 1E. That is, the A-A cross section in FIG. 4A corresponds to the cross section of FIG. 1A, the B-B cross section in FIG. 4B corresponds to the cross section of FIG. 1D, and the C-C cross section in FIG. 4C corresponds to the cross section of FIG. 1E. Here, the labels 2i (i=1, 2) in FIG. 4 correspond to the labels 1i in FIG. 1.

Also for the trench pattern, the trench pattern to be formed in the workpiece 10 is divided into two patterns (first and second patterns) having a lower arrangement density in terms of pattern data processing, and two reticles respectively corresponding to the two patterns (first and second patterns) are used to transfer the two patterns to a resist. Here, in FIG. 4B, the pattern of trenches 21a corresponds to the first pattern, and the pattern of trenches 22a corresponds to the second pattern.

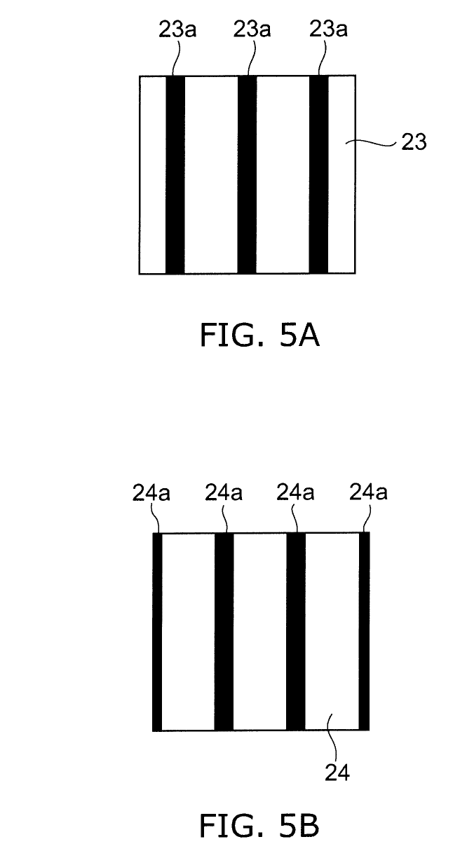

The trench pattern is also subjected to processes similar to those for the hole pattern described above. More specifically, the first resist 21, which is a positive-type resist, is formed entirely on the workpiece 10, and then a reticle (or photomask) 23 shown in FIG. 5A is used to perform selective exposure. The reticle 23 has a structure in which a line-shaped opaque film or half-tone film 23a is selectively formed on a substrate transparent to exposure light.

The aforementioned exposure is followed by development. Thus, as shown in FIG. 4A, a line-shaped pattern of the first resist 21 (corresponding to the first resist 11 in FIG. 1A) is formed on the workpiece 10. This corresponds to an inverted pattern of the trenches 21a (opening pattern) shown in FIG. 4B.

Next, a second resist 22, which is a negative-type resist, is formed on the workpiece 10. Here, again, the thickness of the second resist 22 is adjusted so that the side surface of the first resist 21 (corresponding to the first resist 11 in FIG. 1B) is not entirely covered with the second resist 22 (corresponding to the second resist 12 in FIG. 1B). That is, part of the side surface of the first film 21 (corresponding to the first resist 11 in FIG. 1B) is not covered with the second resist 22 (corresponding to the second resist 12 in FIG. 1B).

Next, a reticle (or photomask) 24 shown in FIG. 5B is used to perform selective exposure on the second resist 22. The reticle 24 has a structure in which an opaque film or half-tone film 24a is selectively formed on a substrate transparent to exposure light. At this exposure time, the first resist 21 is also exposed to light.

The aforementioned exposure is followed by a baking (PEB) process, and further followed by development. The exposed portion of the second resist 22, which is a negative-type resist, undergoes crosslinking and becomes insoluble in the developer. On the other hand, the exposed portion of the first resist 21 (all the line-shaped portions left on the workpiece 10), which is a positive-type resist, becomes soluble in the developer because the protecting group having a dissolution inhibiting effect coupled to the polymer is disengaged. Then, because a portion of the side surface of the first resist 21 is not covered with the second resist 22, the first resist 21 is dissolved in the developer from this portion and removed from the upper surface of the workpiece 10.

The state after development is shown in FIG. 4B. By this development, a combined pattern of the trenches 21a (first pattern) and the trenches 22a (second pattern) is formed in the second resist 22. The trenches 22a are formed by the process in which the unexposed portion of the second resist 22 is dissolved and removed by the developer, and the trenches 21a are formed by the process in which the first resist 21 is dissolved and removed by the same developer. This pattern is a combined pattern of the aforementioned first and second patterns and is formed at a pitch, which is finer than the pattern pitch of the first pattern and the pattern pitch of the second pattern.

Then, the second resist 22 with these trenches 21a and 22a formed therein is used as a mask to selectively etch the underlying workpiece 10. Thus, as shown in FIG. 4C, the desired pattern of trenches 10b is formed in the workpiece 10.

In the configuration shown in FIG. 4C, a plurality of trenches or line-shaped spaces are equally spaced. However, the invention is also applicable to a pattern of trenches arranged at random pitches, and a pattern including a plurality of types of trenches.

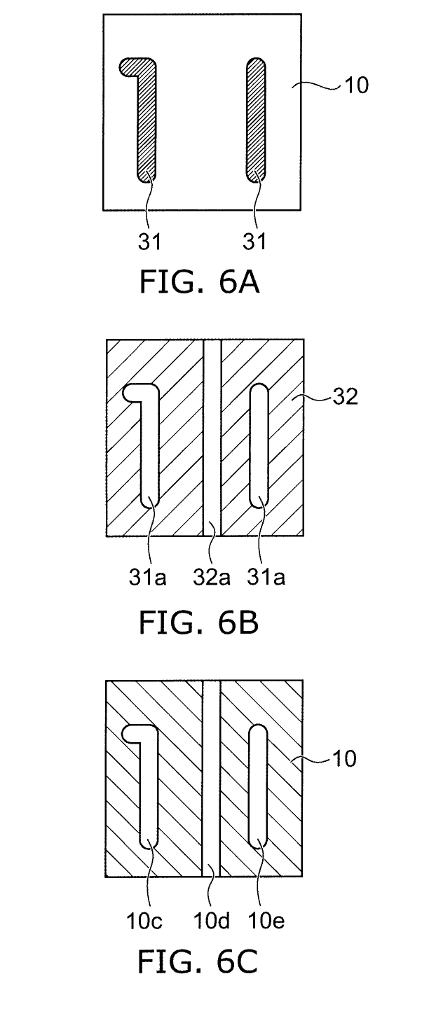

For instance, FIG. 6C shows an example in which three trenches 10c, 10d, and 10e with different pitches and types (in shape and dimension) are formed in the workpiece 10. FIG. 6A is a plan view of the process corresponding to FIG. 4A, FIG. 6B is a plan view of the process corresponding to FIG. 4B, and FIG. 6C is a plan view of the process corresponding to FIG. 4C.

Also for this pattern, the pattern of trenches 10c-10e to be formed in the workpiece 10 is divided into a first pattern 10c and 10e and a second pattern 10d having a lower arrangement density, and then transferred by exposure.

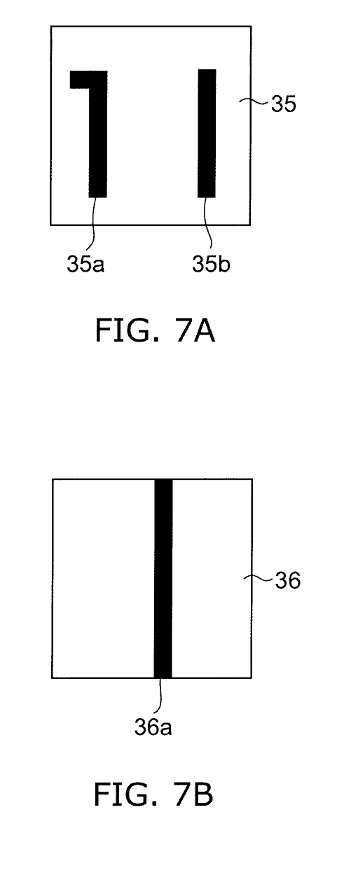

First, as shown in FIG. 6A, a line-shaped pattern of a first resist 31 is formed on the workpiece 10. The first resist 31 is a positive-type resist, which is formed entirely on the workpiece 10, and then a reticle (or photomask) 35 shown in FIG. 7A is used to perform selective exposure. The reticle 35 has a structure in which a line-shaped opaque films or half-tone films 35a and 35b are selectively formed on a substrate transparent to exposure light.

The aforementioned exposure is followed by baking and development. Thus, the first resist 31 is left on the workpiece 10. This corresponds to an inverted pattern of the trenches (opening pattern) 31a shown in FIG. 6B.

Next, a second resist 32, which is a negative-type resist, is formed on the workpiece 10. Here, again, the thickness of the second resist 32 is adjusted so that each side surface of the first resist 31 is not entirely covered with the second resist 32.

Next, a reticle (or photomask) 36 shown in FIG. 7B is used to perform selective exposure on the second resist 32. The reticle 36 has a structure in which an opaque film or half-tone film 36a is selectively formed on a substrate transparent to exposure light. At this exposure time, the first resist 31 is also exposed to light.

The aforementioned exposure is followed by a baking (PEB) process, and further followed by a development process. The exposed portion of the second resist 32, which is a negative-type resist, undergoes crosslinking and becomes insoluble in the developer. On the other hand, the exposed portion of the first resist 31 (all the line-shaped portions left on the workpiece 10), which is a positive-type resist, becomes soluble in the developer because the protecting group having a dissolution inhibiting effect coupled to the polymer is disengaged. Then, because a portion of each side surface of the first resist 31 is not covered with the second resist 32, the first resist 31 is dissolved in the developer from this portion and removed from above the workpiece 10.

The state after development is shown in FIG. 6B. By this development, a combined pattern of the trenches 31a (first pattern) and the trenches 32a (second pattern) is formed in the second resist 32. The trenches 32a are formed by the process in which the unexposed portion of the second resist 32 is dissolved and removed by the developer, and the trenches 31a are formed by the process in which the first resist 31 is dissolved and removed by the same developer. The pattern of the trenches 31a and 32a is a combined pattern of the first pattern 31a and the second pattern 32a and is formed at a pitch, which is finer than the pattern pitch of the first pattern 31a and the pattern pitch of the second pattern 32a.

Then, the second resist 32 with these trenches 31a and 32a formed therein is used as a mask to selectively etch the underlying workpiece 10. Thus, as shown in FIG. 6C, the desired pattern of trenches 10c, 10d, and 10e is formed in the workpiece 10.

### Second Embodiment

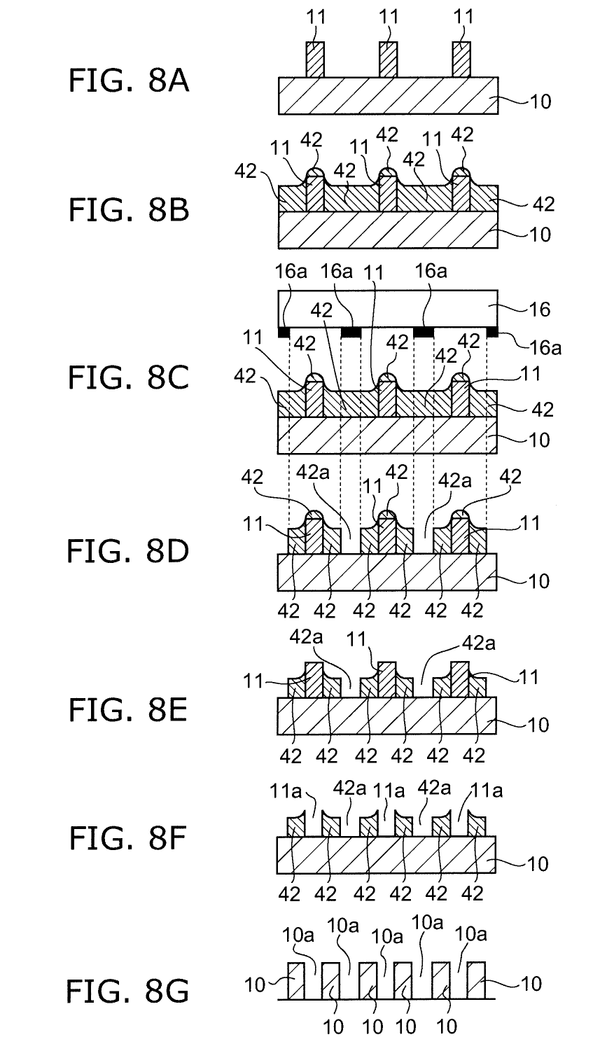

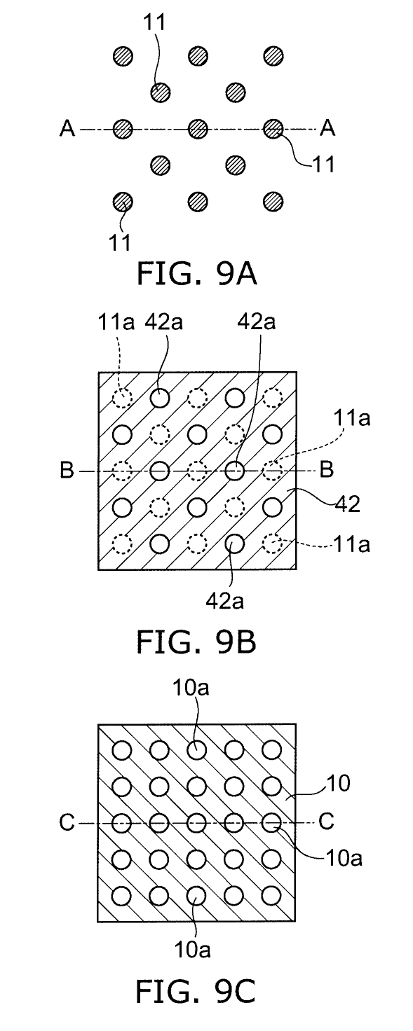

FIGS. 8A to 8G are schematic cross-sectional views showing a process for manufacturing a semiconductor device according to a second embodiment of the invention. FIGS. 9A to 9C show plan views of particular processes in FIG. 8. The A-A cross section in FIG. 9A corresponds to FIG. 8A, the B-B cross section in FIG. 9B corresponds to FIG. 8F, and the C-C cross section in FIG. 9C corresponds to FIG. 8G.

Also in this embodiment, like the above embodiment described with reference to FIGS. 1A to 2C, when a plurality of holes 10a corresponding to contact holes in a semiconductor device are formed in a workpiece 10, the contact hole pattern is divided into two patterns (first and second patterns) having a lower arrangement density in terms of pattern data processing, and two reticles respectively corresponding to the two patterns (first and second patterns) are used to transfer the two patterns to a resist. Here, in FIG. 9B, the pattern of holes 11a shown by dashed lines corresponds to the first pattern, and the pattern of holes 42a shown by solid lines corresponds to the second pattern.

First, as shown in FIGS. 8A and 9A, a pattern of a first resist 11 is formed on the workpiece 10. The first resist 11 is formed entirely on the workpiece 10, and then a reticle shown in FIG. 3A is used to perform selective exposure, baking and development. Thus, the first resist 11 is left on the workpiece 10 in a pillar configuration, which corresponds to an inverted pattern of the holes 11a (opening pattern) shown in FIG. 9B. The first resist 11 may be a positive-type resist or negative-type resist. In the case where the first resist 11 is a negative-type resist, the transparent portion and the opaque film or half-tone film portion 15a in the reticle 15 shown in FIG. 3A are reversed.

Next, as shown in FIG. 8B, a second resist 42 is formed on the workpiece 10. Here, there is no need to control part of the first resist 11 not to be covered with the second resist 42. That is, in this embodiment, the first resist 11 may be entirely covered with the second resist 42.

Here, the combination of materials for the first resist 11 and the second resist 42 needs to be such that in the dry process described later, the etching selective ratio of the first resist 11 to the second resist 42 is high enough to enable selective etching of the first resist 11. In this embodiment, as described later, the first resist 11 is selectively removed by an ashing process using oxygen gas, for instance. To this end, oxides of all the elements constituting the first resist 11 have a relatively high vapor pressure, and the second resist 42 contains an element whose oxide has a relatively low vapor pressure. For instance, the first resist 11 is made of an organic polymer resist, and the second resist 42 is made of a resist containing silicon as an element whose oxide has a relatively low vapor pressure.

Next, as shown in FIG. 8C, a reticle (or photomask) 16 shown in FIG. 3B is used to perform selective exposure on the second resist 42. The pattern image transferred to the second resist 42 by this exposure corresponds to the pattern of the holes 42a (opening pattern) shown in FIG. 9B. Although FIG. 8C shows the case where the second resist 42 is a negative-type resist, the second resist 42 may be a positive-type resist. In the case where the second resist 42 is a positive-type resist, the transparent portion and the opaque film or half-tone film portion 16a in the reticle 16 shown in FIG. 3B are reversed.

This exposure is followed by a baking (PEB) process, and further followed by development. Thus, as shown in FIG. 8D, the second resist 42 is selectively removed, and holes 42a are formed. During this development, the first resist 11 is covered with the insoluble portion of the second resist 42 and not dissolved in the developer, but left on the workpiece 10. The developer can be an aqueous solution using acid-base reaction, such as tetramethylammonium aqueous solution, or an organic solvent using difference of polarity.

Next, RIE (reactive ion etching) using a gas containing fluorine or chlorine is performed to remove the second resist 42 on the upper surface of the first resist 11. Thus, as shown in FIG. 8E, the upper surface of the first resist 11 is uncovered.

Next, ashing or RIE using an oxygen-containing gas is performed to remove the first resist 11 from the upper surface of the workpiece 10 as shown in FIG. 8F. FIG. 9B shows a plan view corresponding to FIG. 8F. Thus, by the aforementioned development and dry process (such as RIE and ashing), a combined pattern of the holes 11a (first pattern) and the holes 42a (second pattern) is formed in the second resist 42. The holes 42a are formed in the second resist 42 where it is removed by selective exposure, baking and development, and the holes 11a are formed in the first resist 11 where it is removed by the dry process after the development of the second resist 42. The hole pattern is a combined pattern of the first pattern 11a and the second pattern 42a described above and is formed at a pitch, which is finer than the pattern pitch of the first pattern 11a and the pattern pitch of the second pattern 42a.

Alternatively, the second resist 42 on the upper surface of the first resist 11 may be removed before the exposure process shown in FIG. 8C. In this case, when the second resist 42 is developed, the second resist 42 is selectively removed, and the first resist 11 left on the workpiece 10 can also be removed by the same developer. Alternatively, the first resist 11 may be removed by a dry process as described above (dry development).

Then, the second resist 42 with these holes 11a and 42a formed therein is used as a mask to selectively etch the underlying workpiece 10. Thus, as shown in FIGS. 8G and 9C, the desired pattern of holes 10a is formed in the workpiece 10.

Thus, also in this embodiment, a fine opening pattern, which is difficult to form by single exposure, can be formed at low cost without using a hard mask.

In this embodiment, the second resist 42 loses film thickness during RIE for uncovering the upper surface of the first resist 11 and during ashing or RIE for removing the first resist 11. Furthermore, in view of the process for removing the second resist 42 on the upper surface of the first resist 11 by RIE, it is undesirable if this portion has an excessively large thickness. Hence, taking these into consideration, it is necessary to control the thickness of the second resist 42 at the time of application in the process of FIG. 8B.

Furthermore, the combination of materials in the first resist 11 and the second resist 42 is not limited to the combination of an organic polymer resist and a silicon-containing resist, as long as the etching selective ratio of the first resist 11 to the second resist 42 is high enough to enable the first resist 11 to be selectively removed without losing the thickness of the second resist 42 significantly.

Furthermore, in forming the second resist 42, for instance, a solution of the material for the second resist 42 dissolved in an organic solvent is applied onto the workpiece 10 and then dried. Here, the combination of materials needs to be determined so that the first resist 11 is not dissolved when the second resist 42 is applied. Moreover, it may be determined so that the first resist 11 is not dissolved when the second resist 42 is developed. For instance, before the second resist 42 is formed, the first resist 11 can be insolubilized by ion implantation or ultraviolet irradiation. Alternatively, before the second resist 42 is formed, the first resist 11 can be insolubilized by thermal crosslinking.

Alternatively, it is also useful to make a difference in PEB (post-exposure bake) temperature between the first resist 11 and the second resist 42. In the positive-type resist, at the time of PEB, acid generated by exposure causes disengagement of the protecting group, and the positive-type resist becomes developer-soluble. In the negative-type resist, at the time of PEB, acid generated by exposure causes crosslinking reaction. The first-layer resist and the second-layer resist are configured to undergo chemical reaction at different temperatures so that the first-layer resist is not dissolved by the exposure and the development of the second-layer resist. For instance, in the case where the first resist 11 is a positive-type resist and the second resist 42 is a negative-type resist, the activation energy of disengaging the protecting group in the first resist 11 is set to be higher than the activation energy of causing crosslinking reaction in the second resist 42 so that the protecting group in the first resist 11 is not disengaged at the time of PEB of the second resist 42.

Alternatively, it is also useful to set the sensitivity of the first resist 11 to be poorer than the sensitivity of the second resist 42 so that the first resist 11 does not become soluble at the energy during exposure of the second resist 42.

Also in this embodiment, a method for forming a pattern of holes periodically arranged at an equal pitch has been described. However, it is also possible to form a pattern of holes non-periodically arranged at random pitches. Furthermore, the size of holes is not limited to a single size, but this method can form a pattern including elliptical holes having different aspect ratios. Moreover, this embodiment is not limited to hole patterns but is also applicable to forming trench patterns.

### Third Embodiment

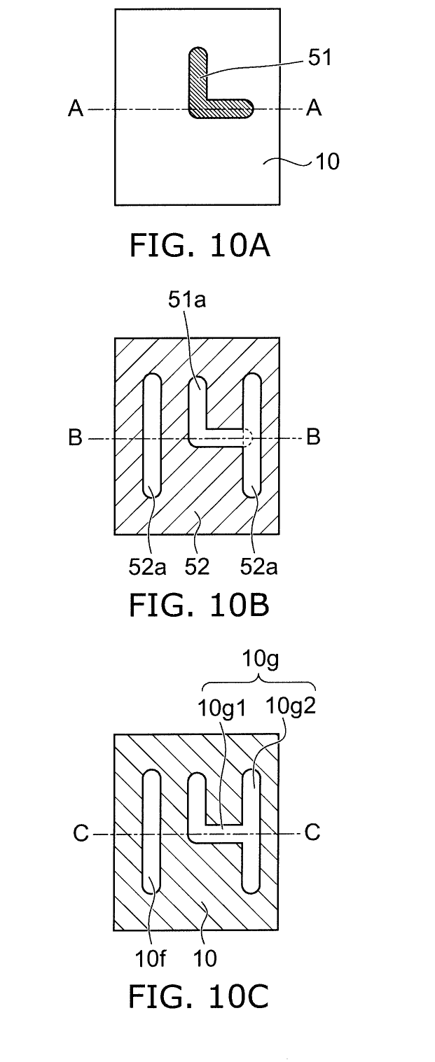

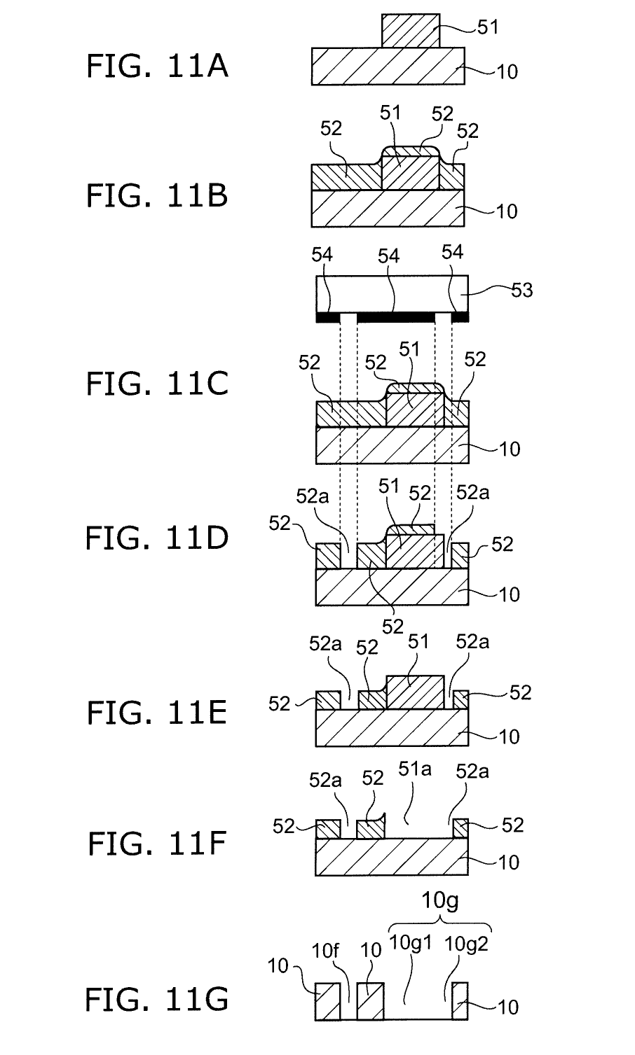

Next, a third embodiment of the invention is described with reference to FIGS. 10A to 11G. In this embodiment, an opening pattern, which is originally a single pattern, is divided into two, a first pattern and a second pattern, and the divided patterns are finally joined.

In this embodiment, patterns 10f and 10g as shown in FIG. 10C are formed as an opening pattern (space pattern) in a workpiece 10.

A method for double patterning is described in the case where the pitch between three space patterns extending vertically in FIG. 10C is so narrow that a resist pattern corresponding to the three space patterns cannot be formed by single exposure. More specifically, it is necessary to separately form a resist pattern corresponding to the space extending vertically at the center and a resist pattern corresponding to two spaces extending vertically on both sides of the center space pattern.

In this embodiment, for instance, the right-side pattern 10g is divided into two, a first pattern 10g1 made of the space extending horizontally and the space extending vertically at the center and a second pattern 10g2 made of the space extending vertically on the right side. The resist pattern is divided into a first pattern 51a made of the space extending horizontally and the space extending vertically at the center and a second pattern 52a made of the space extending vertically. In this case, a junction occurs between the two divided patterns, the first pattern and the second pattern. The second pattern 10g2 made of the space extending vertically on the right side and the left-side pattern 10f are formed simultaneously in the resist pattern 52a.

FIGS. 11A to 11G are schematic cross-sectional views showing a process for manufacturing a semiconductor device according to the third embodiment of the invention. FIGS. 10A to 10C show plan views of particular processes in FIGS. 11A to 11G. The A-A cross section in FIG. 10A corresponds to FIG. 11A, the B-B cross section in FIG. 10B corresponds to FIG. 11F, and the C-C cross section in FIG. 10C corresponds to FIG. 11G.

First, as shown in FIGS. 10A and 11A, a pattern 51 made of the first resist is formed on the workpiece 10. The first resist pattern 51 corresponds to an inverted pattern of the pattern 10g1, which is an space pattern, and is formed on the workpiece 10 in a line configuration.

Next, as shown in FIG. 11B, a second resist 52 is formed on the workpiece 10. The second resist 52 is applied entirely on the workpiece 10 and covers the first resist 51.

Here, the combination of materials for the first resist 51 and the second resist 52 needs to be such that the etching selective ratio of the first resist 51 to the second resist 52 is high enough to enable selective etching of the first resist 51 in the dry process (ashing) described later. For instance, the first resist 51 is selectively removed by an ashing process using oxygen gas, which is also described later in this embodiment. To this end, oxides of all the elements constituting the first resist 51 have a relatively high vapor pressure, and the second resist 52 contains an element whose oxide has a relatively low vapor pressure. For instance, the first resist 51 is made of an organic polymer resist, and the second resist 52 is made of a resist containing silicon as an element whose oxide has a relatively low vapor pressure.

Next, as shown in FIG. 11C, a reticle (or photomask) 53 with an opaque film or half-tone film 54 formed on a substrate transparent to exposure light is used to perform selective exposure on the second resist 52. The pattern image transferred to the second resist 52 by this exposure is labeled 52a in FIG. 10B and corresponds to the patterns 10f and 10g2 shown in FIG. 10C.

Here, the length of the first resist 51 corresponding to the inverted pattern of the pattern 10g1 needs to be adjusted so that its end portion slightly overlaps the position where the pattern 10g2 is to be formed.

This exposure is followed by baking (PEB), and further followed by development. Thus, as shown in FIG. 11D, the second resist 52 is selectively removed, and trenches 52a are formed.

Next, RIE using a gas containing fluorine or chlorine is performed to remove the second resist 52 left on the upper surface of the first resist 51. Thus, as shown in FIG. 11E, the upper surface of the first resist 51 is uncovered.

Alternatively, the second resist 52 on the upper surface of the first resist 51 may be removed before the exposure process shown in FIG. 11C. In this case, when the second resist 52 is developed, the second resist 52 is selectively removed, and the first resist 51 left on the workpiece 10 can also be removed by the same developer.

Next, ashing or RIE using an oxygen-containing gas is performed to remove the first resist 51 from the upper surface of the workpiece 10. The state in which the first resist 51 has been removed is shown in FIGS. 10B and 11F. The trench 51a formed by removal of the first resist 51 joins with the trench 52a, which is formed in the second resist 52 at the time of the aforementioned development. That is, by the aforementioned development and dry process (such as RIE and ashing), a combined trench pattern of the trench 51a corresponding to the first pattern 10g1 and the trench 52a corresponding to the second pattern 10g2 is formed in the second resist 52.

Alternatively, the second resist 52 on the upper surface of the first resist 51 may be removed before the exposure process shown in FIG. 11C. In this case, when the second resist 52 is developed, the second resist 52 is selectively removed, and the first resist 51 left on the workpiece 10 can also be removed by the same developer. Alternatively, the first resist 51 may be removed by a dry process as described above (dry development).

Then, the second resist 52 with these trench patterns formed therein is used as a mask to selectively etch the underlying workpiece 10. Thus, as shown in FIGS. 10C and 11G, the desired pattern of trenches 10f and 10g is formed in the workpiece 10.

Thus, also in this embodiment, a fine opening pattern, which is difficult to form by single exposure, can be formed at low cost without using a hard mask.

### Fourth Embodiment

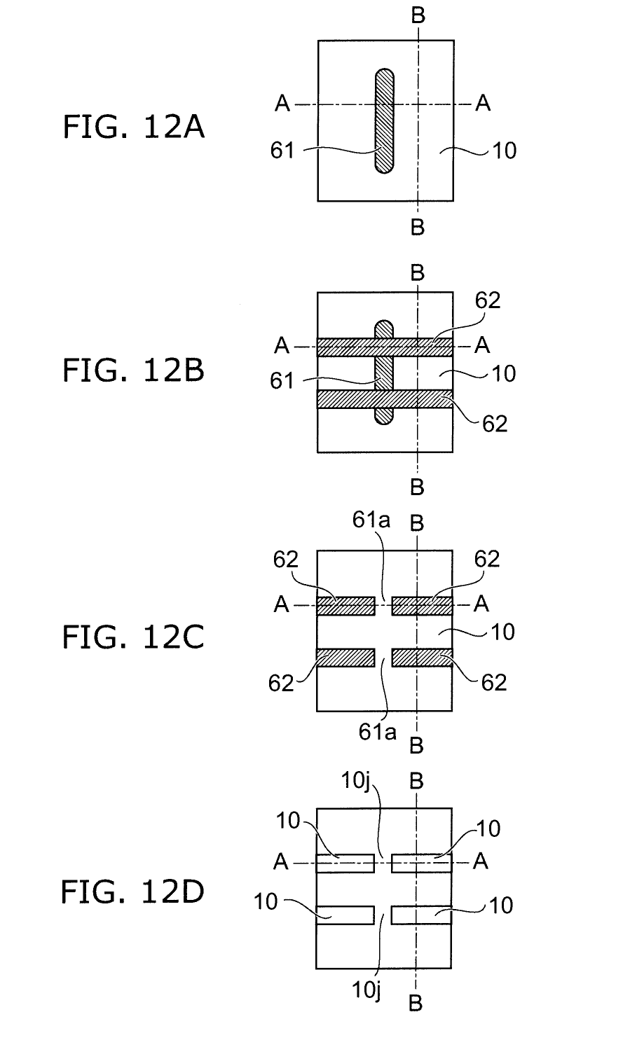

Next, a fourth embodiment of the invention is described with reference to FIGS. 12A to 14G.

In this embodiment, as shown in FIG. 12D, a pattern including a narrow space pattern 10j between line-shaped workpiece patterns 10 is formed. However, it is difficult to form a narrow space pattern 10j between line-shaped patterns 10 by single exposure. This is because the space between lines becomes wide by single exposure, and hence it is difficult to obtain the desired narrow space pattern.

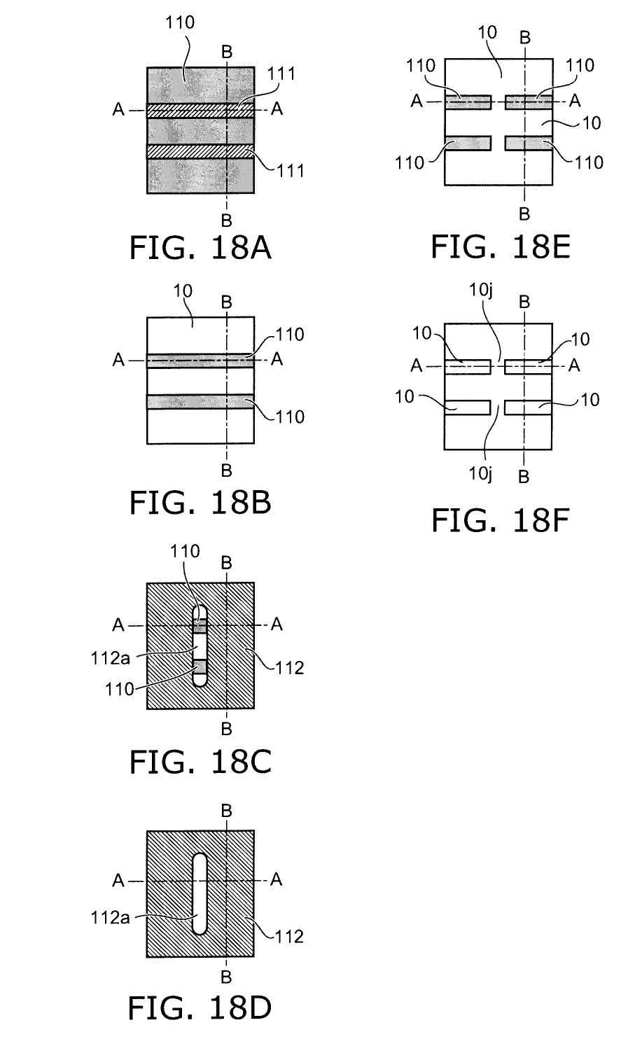

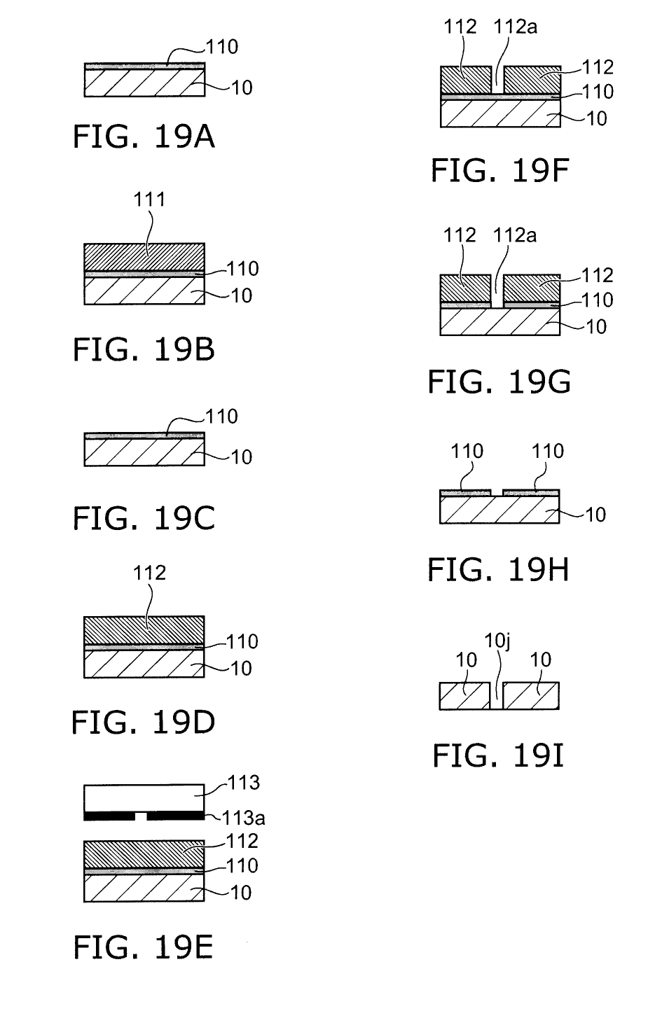

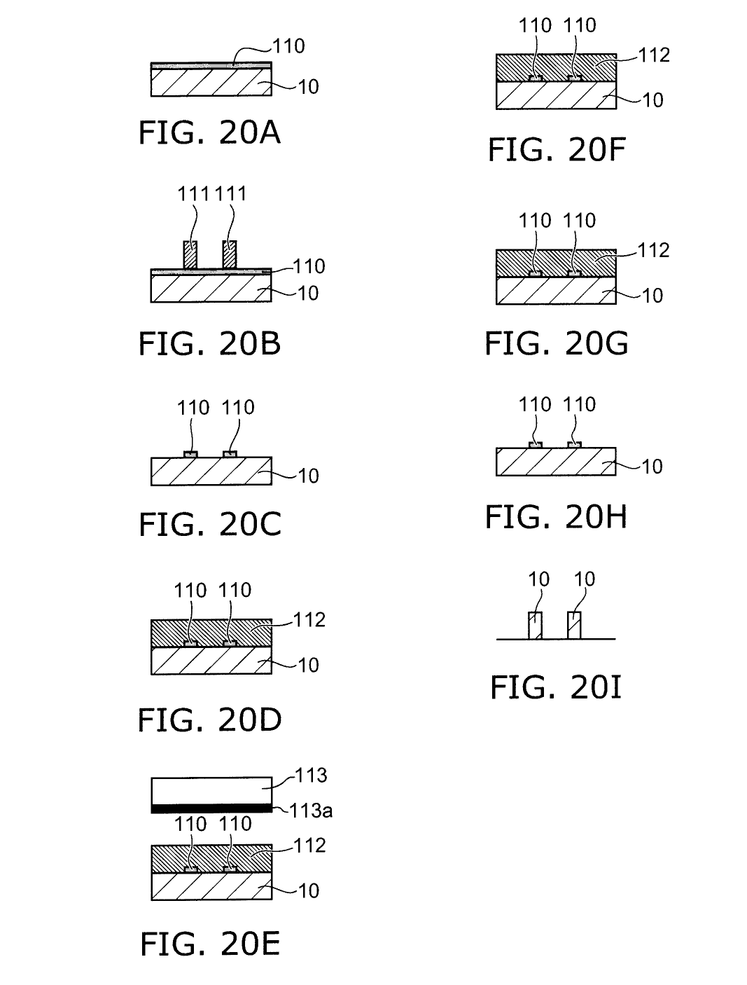

FIGS. 18A to 18F are schematic cross-sectional views showing a process for manufacturing a semiconductor device of a second comparative example for comparison with the fourth embodiment of the invention. FIGS. 19A to 191 are process cross-sectional views of the A-A cross section in FIGS. 18A to 18F, and FIGS. 20A to 20I are process cross-sectional views of the B-B cross section in FIGS. 18A to 18F.

The A-A cross section in FIG. 18A corresponds to FIG. 19B, the A-A cross section in FIG. 18B corresponds to FIG. 19C, the A-A cross section in FIG. 18C corresponds to FIG. 19F, the A-A cross section in FIG. 18D corresponds to FIG. 19G, the A-A cross section in FIG. 18E corresponds to FIG. 19H, and the A-A cross section in FIG. 18F corresponds to FIG. 19I.

The B-B cross section in FIG. 18A corresponds to FIG. 20B, the B-B cross section in FIG. 18B corresponds to FIG. 20C, the B-B cross section in FIG. 18C corresponds to FIG. 20F, the B-B cross section in FIG. 18D corresponds to FIG. 20G, the B-B cross section in FIG. 18E corresponds to FIG. 20H, and the B-B cross section in FIG. 18F corresponds to FIG. 20I.

FIGS. 18A to 20I show a process using a hard mask. In this case, a line pattern is formed previously. First, as shown in FIGS. 19A and 20A, a hard mask 110 is formed on the workpiece 10. Next, as shown in FIGS. 18A, 19B, and 20B, a line pattern is formed from a first-layer resist 111 on the hard mask 110. Next, pattern transfer is performed by using the first-layer resist pattern 111 as a mask to process the hard mask 110. Subsequently, the first-layer resist pattern 111 is removed by ashing. Thus, as shown in FIGS. 18B, 19C, and 20C, a line pattern of the hard mask 110 is obtained.

Next, as shown in FIGS. 19D and 20D, a second-layer resist 112 is applied. Then, as shown in FIGS. 19E and 20E, exposure is performed by using a reticle 113 with an opaque film (or half-tone film) 113a formed on a light-transparent substrate.

Subsequently, by development, as shown in FIGS. 18C and 19F, a trench 112a is formed in the second-layer resist 112. The trench 112a is a space pattern for forming a narrow space pattern 10j (FIG. 18F).

Next, as shown in FIGS. 18D and 19G, the second-layer resist pattern 112 is used as a mask to process the hard mask 110. Subsequently, the second-layer resist pattern 112 is removed by ashing. Thus, as shown in FIGS. 18E, 19H, and 20H, the desired hard mask pattern 110 is obtained. Furthermore, the hard mask pattern 110 is used as a mask to etch the workpiece 10. Thus, as shown in FIGS. 18F, 19I, and 20I, the desired workpiece pattern 10 is obtained.

In this second comparative example, a horizontally continuous line pattern of the hard mask 110 is first formed, and a second-layer resist 112 is applied thereon. Then, a trench 112a is formed in the second-layer resist 112, and the hard mask 110 exposed to the trench 112a is selectively etched to form a line-shaped hard mask pattern 110 having a narrow space, which is used as a mask to process the workpiece. However, in this case, the process for the hard mask is performed in addition to the resist process. This increases the number of processes and results in cost increase.

In contrast, in this embodiment, the pattern is divided into a first pattern corresponding to the narrow space pattern and a second pattern corresponding to the line-shaped pattern, and double patterning is performed without using a hard mask as described below.

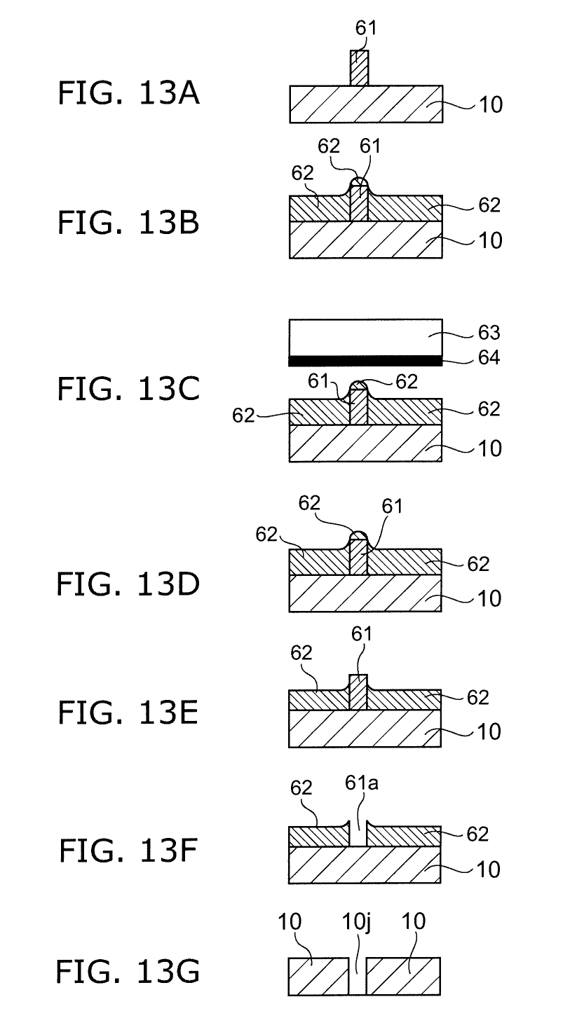

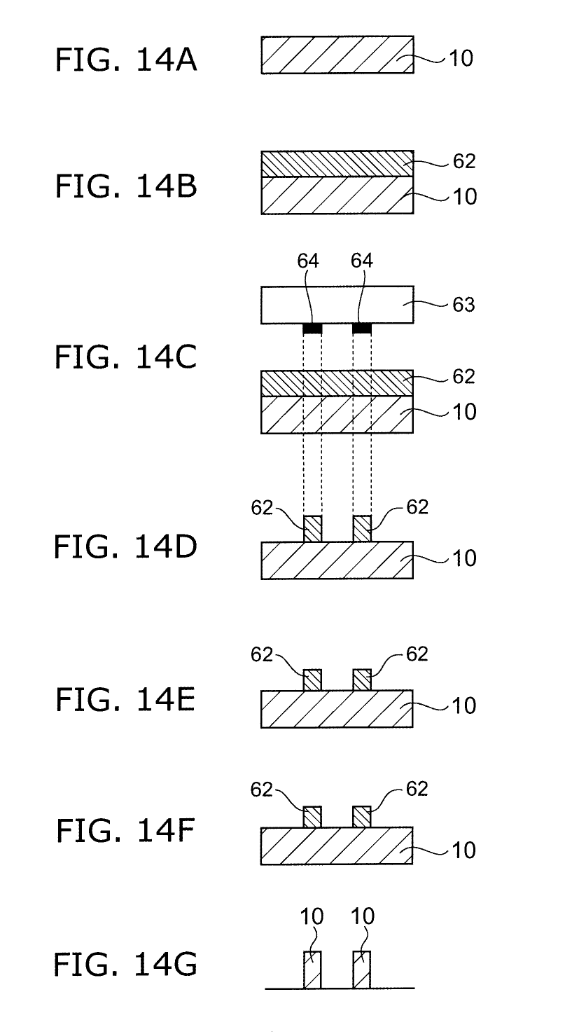

FIGS. 12A to 12D are schematic plan views showing a process for manufacturing a semiconductor device according to the fourth embodiment of the invention. FIGS. 13A to 13G are process cross-sectional views of the A-A cross section in FIGS. 12A to 12D, and FIGS. 14A to 14G are process cross-sectional views of the B-B cross section in FIGS. 12A to 12D. The A-A cross section in FIG. 12A corresponds to FIG. 13A, the A-A cross section in FIG. 12B corresponds to FIG. 13D, the A-A cross section in FIG. 12C corresponds to FIG. 13F, and the A-A cross section in FIG. 12D corresponds to FIG. 13G. The B-B cross section in FIG. 12A corresponds to FIG. 14A, the B-B cross section in FIG. 12B corresponds to FIG. 14D, the B-B cross section in FIG. 12C corresponds to FIG. 14F, and the B-B cross section in FIG. 12D corresponds to FIG. 14G.

First, as shown in FIGS. 12A, 13A, and 14A, a line-shaped pattern of a first resist 61 is formed on the workpiece 10. This pattern of the first resist 61 is a pattern for forming a narrow space pattern 10j shown in FIG. 12D and is a remaining pattern corresponding to an inverted pattern of the pattern 10j, which is an opening pattern.

Next, as shown in FIGS. 13B and 14B, a second resist 62 is formed on the workpiece 10. The second resist 62 is applied entirely on the workpiece 10 and covers the first resist 61.

Here, the combination of materials for the first resist 61 and the second resist 62 needs to be such that the etching selective ratio of the first resist 61 to the second resist 62 is high enough to enable selective etching of the first resist 61 in the dry etching process described later. For instance, the first resist 61 is selectively removed by an ashing process using oxygen gas which is also described later in this embodiment. To this end, oxides of all the elements constituting the first resist 61 have a relatively high vapor pressure, and the second resist 62 contains an element whose oxide has a relatively low vapor pressure. For instance, the first resist 61 is made of an organic polymer resist, and the second resist 62 is made of a resist containing silicon as an element whose oxide has a relatively low vapor pressure.

Next, as shown in FIGS. 13C and 14C, a reticle (or photomask) 63 with an opaque film or half-tone film 64 formed on a substrate transparent to exposure light is used to perform selective exposure on the second resist 62.

This exposure is followed by a baking (PEB) process, and further followed by a development process. Thus, as shown in FIGS. 12B, 13D, and 14D, the second resist 62 is selectively removed. Here, the second resist 62 is a positive-type resist. Thus, the exposed portion is dissolved in the developer, and the unexposed portion is left in a line configuration. During this development, the first resist 61 is not dissolved but left on the workpiece 10. As shown in FIG. 12B, the second resist 62 crosses over the first resist 61.

Next, RIE using a gas containing fluorine or chlorine is performed to remove the second resist 62 on the first resist 61. Thus, as shown in FIGS. 13E and 14E, the upper surface of the first resist 61 is uncovered.

Next, ashing or RIE using an oxygen-containing gas is performed to remove the first resist 61 from the upper surface of the workpiece 10. By removal of the first resist 61, as shown in FIGS. 12C, 13F, and 14F, a narrow space 61a is formed at a midpoint of the line-shaped second resist 62. That is, each line of the second resist 62 is split by the narrow space 61a.

Then, the second resist 62 with the narrow space 61a formed therein is used as a mask to selectively etch the workpiece 10. Thus, as shown in FIGS. 12D, 13G, and 14G, a pattern with the narrow space pattern 10j formed between the line-shaped patterns 10 is obtained.

Thus, also in this embodiment, a narrow space pattern 10j, which is a fine opening pattern being difficult to form by single exposure, can be formed at low cost without using a hard mask.

The embodiments of the invention have been described with reference to examples. However, the invention is not limited thereto but can be variously modified within the spirit of the invention.

In the above embodiments, an anti-reflective coating may be formed between the workpiece 10 and the resist (first resist, second resist). As a comparative example, in double patterning using a hard mask, the anti-reflection coating needs to be formed separately at the time of forming the first resist and at the time of forming the second resist. In contrast, in the above embodiments of the invention, after the remaining pattern (line pattern, island pattern and dot pattern) of the first resist is formed on the workpiece, the second resist is formed on the workpiece with the remaining pattern of the first resist left without removal. Hence, the anti-reflective coating formed on the workpiece at the time of forming the first resist can still be used as an anti-reflective coating at the time of exposure of the second resist. Thus, also in the case of forming an anti-reflective coating, the embodiments of the invention can be performed in a smaller number of processes and lower cost than the process using a hard mask.

There can be some variations of the method for dissolving and removing the first resist by the same developer at the time of developing the second resist as described in the above first embodiment.

In one variation, the method can be based on the difference in developer solubility between the first resist and the second resist. More specifically, the first resist is selected so that only one of its exposed portion and unexposed portion selectively dissolves in a relatively dilute developer, whereas all the resist, whether exposed or unexposed, dissolves in a relatively concentrated developer. On the other hand, the second resist is selected so that only one of its exposed portion and unexposed portion selectively dissolves in the relatively concentrated developer. Then, after the first resist is patterned by the relatively dilute developer to form a remaining pattern of the first resist, when the second resist is developed by using the relatively concentrated developer, the first resist left on the workpiece can be removed. Thus, it is possible to obtain the desired pattern in which the pattern obtained by the development of the second resist and the pattern obtained by the removal of the first pattern are combined.

In another variation, the first resist can be a positive-type resist with a thermal acid generator (TAG) added thereto. In this case, the TAG is selected so that it does not generate acid at PEB temperature after exposure of the first resist but generates acid when heated at higher temperatures than the PEB temperature.

By performing a baking process before development of the second resist, acid is generated from the TAG in the first resist left on the workpiece to disengage the protecting group, thereby solubilizing the first resist. Thus, the first resist can also be dissolved and removed when the second resist is developed. More preferably, the PEB process for the second resist also serves as the baking process for generating acid in the first resist. This can suppress the increase in the number of process steps and is advantageous to cost reduction.

Furthermore, in the above second and subsequent embodiments, the method for removal of the portion of the second resist on the first resist is not limited to RIE, but the following methods can also be used.

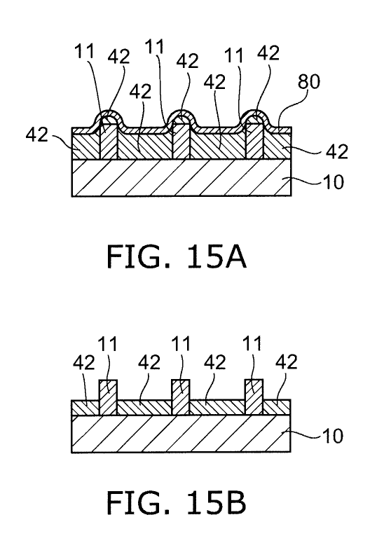

As shown in FIG. 15A, after a pattern of the first resist composed of a positive-type resist is formed on the workpiece 10, a second resist 42 is applied onto the workpiece. The processes so far are the same as the processes of FIGS. 8A and 8B described above. Subsequently, a film 80 containing a TAG is formed on the second resist 42. Subsequently, baking is performed to generate acid from the TAG. By the action of the acid thus generated, the protecting group of the polymer of the second resist 42 on the surface in contact with the film 80 is disengaged. By development, the portion of the second resist 42 covering the upper surface and part of the side surface of the first resist 11 is removed. Thus, as shown in FIG. 15B, part of the first resist 11 is uncovered.

Alternatively, part of the first resist 11 can also be uncovered by dissolving the surface of the second resist using a solvent. More specifically, a polar solvent can be used to selectively remove only the second resist and to uncover the first resist. For instance, the polarity of the second resist is set to be higher than the polarity of the first resist so that the second resist dissolves in the aforementioned polar solvent whereas the first resist does not dissolve therein. The polar solvent can be an organic solvent or an aqueous solution.

The resist constituting the second resist can be such that its insolubilized portion (exposed portion for a negative-type resist shown in FIG. 8C) slightly dissolves in the developer and reduces the thickness of the portion left on the workpiece when the second resist is developed. In this case, when the second resist is developed, the surface of the second resist covering the first resist dissolves and the first resist appears.

1. A method for manufacturing a semiconductor device, comprising:
forming a first resist on a workpiece;
patterning the first resist by performing selective exposure, baking, and development on the first resist;
forming a second resist on the workpiece after the patterning the first resist;
patterning the second resist by performing selective exposure, baking, and development on the second resist to selectively remove a part of the second resist and remove the first resist left on the workpiece; and
processing the workpiece by using the patterned second resist as a mask.

2. The method according to claim 1, wherein the first resist is made of a material not dissolving in a solvent of the second resist during forming the second resist.

3. The method according to claim 1, wherein a part of the first resist is not covered with the second resist and the first resist is removed during developing the second resist by dissolving also in a developer used for developing the second resist.

4. The method according to claim 3, wherein the first resist is patterned in a pillar shape, and a part of a side surface of the pillar-shaped pattern of the first resist is not covered with the second resist.

5. The method according to claim 3, wherein the first resist is a positive-type resist, and the second resist is a negative-type resist.

6. The method according to claim 1, wherein the patterning the second resist includes
performing selective exposure and baking the second resist after forming the second resist on the workpiece,
developing the second resist by a solution after the baking of the second resist;
removing a portion of the second resist covering a pattern of the first resist after developing the second resist by the solution, and
removing the first resist after removing the portion of the second resist covering the pattern of the first resist.

7. The method according to claim 6, further comprising:
insolubilizing the first resist against a solvent of the second resist before forming the second resist.

8. The method according to claim 6, wherein the portion of the second resist covering the pattern of the first resist is removed by a dry etching process.

9. The method according to claim 6, wherein the first resist is removed by a dry etching process.

10. The method according to claim 6, wherein the first resist is an organic polymer resist, and the second resist is a silicon-containing resist.

11. The method according to claim 6, wherein
the pattern of the first resist is a line-shaped pattern,
a pattern of the second resist is a line-shaped pattern overlapping and crossing the pattern of the first resist, and
a narrow space splitting the line-shaped pattern of the second resist is formed by removing the pattern of the first resist.

12. The method according to claim 1, wherein the patterning the second resist includes
removing a portion of the second resist covering the pattern of the first resist after forming the second resist,
performing selective exposure and baking the second resist after removing the portion of the second resist covering the pattern of the first resist,
developing the second resist by a solution, and
removing the first resist.

13. The method according to claim 12, further comprising:
insolubilizing the first resist against a solvent of the second resist before forming the second resist.

14. The method according to claim 12, wherein the portion of the second resist covering the pattern of the first resist is removed by a dry etching process.

15. The method according to claim 12, wherein the first resist is removed by a dry etching process.

16. The method according to claim 12, wherein the first resist is an organic polymer resist, and the second resist is a silicon-containing resist.

17. The method according to claim 12, wherein the first resist is removed during developing the second resist by dissolving also in a developer used for developing the second resist.

18. The method according to claim 12, wherein
the pattern of the first resist is a line-shaped pattern,
the pattern of the second resist is a line-shaped pattern overlapping and crossing the pattern of the first resist, and
a narrow space splitting the line-shaped pattern of the second resist is formed by removing the pattern of the first resist.

19. The method according to claim 1, wherein
the pattern to be formed in the workpiece is divided into a first pattern and a second pattern,
the selective exposure to the first resist is performed by using a first reticle corresponding to the first pattern, and
the selective exposure to the second resist is performed by using a second reticle corresponding to the second pattern.

20. The method according to claim 1, wherein a pattern of the first resist corresponds to an inverted pattern of a pattern to be formed as a space or a hole in the workpiece.
